(19) United States
(12) Patent Application Publication
(10) Pub. No.: US 2008/0224750 A1
(43) Pub. Date: Sep. 18, 2008

(54) Digital delay architecture

(75) Inventor: Ajit Kumar Reddy, Matawan, NJ (US)

Correspondence Address: Brian C. Oakes;Tyco Electronics, Suite 140, 4550 New Linden Hill Road, Wilmington, DE, 19808-2952, US

(73) Assignee: M/A-Com, Inc.

(21) Appl. No.: 11/717,427

(22) Filed: Mar. 13, 2007

(51) Int. Cl. H03H 11/26

(52) U.S. Cl. 327/276

(57) ABSTRACT

A digital delay architecture and a digital delay method are provided. The digital delay architecture includes at least one shifter, at least one adder connected to the at least one shifter and a plurality of registers storing at least an output of the at least one adder and an original sampled signal. The plurality of registers are selectable to define a fractional delay value.

### BACKGROUND OF THE INVENTION

This invention relates generally to digital systems with fractional structures, and more particularly, to systems providing digital delays, especially fractional digital delays.

Digital delay lines are used in electronic systems to compensate for delays in other portions of the systems. A digital delay line ensures that an output signal is delayed by an amount or increment thereof, such as a predetermined time period, relative to an input signal. Thus, an input signal is delayed a certain amount of time (e.g., n time units) by a delay device such that a time delay is introduced between the input to the delay device and the output of the delay device. The delay device may include one or more taps for sampling the digital signal and having different outputs providing different incremental delays. The delay devices may be, for example, a sequential logic element used in digital logic and digital signal processing where the output signal is the same as the input signal at a delayed time.

One application for digital delay lines is in systems having both digital and analog circuitry, such as communication systems, and in particular wireless communication systems (e.g., cellular communication system). In these systems, the digital delay line attempts to compensate for analog delay introduced by the analog circuitry, for example, the analog delay introduced by the analog components, such as filters, capacitors, inductors, etc. If the digital circuitry does not properly compensate for the analog delay problems can arise. For example, the communication system may not be able to meet certain spectral requirements and/or other processes within the system may not be able to function properly because those processes require an accurate measure of the incoming analog signal. As a result, some audio may be distorted or missed entirely.

Known systems for providing delay lines perform an integral delay process that requires multipliers and adders. These systems require complex calculations and processing that can add latency to the overall system and the need for complex controls. Additionally, more power is required to operate these components and more space is required to house these components.

An alternative to providing a digital delay line is to sample the incoming audio signal at a high rate in order to properly process the signal. It is often not easy to sample at these high rates and results in increased power consumption and the need for more components to provide this high rate of sampling, which also results in the need for a larger case for the overall unit. Further, at higher frequency transmissions, for example, 4 GHz, sampling at the required rates is not even possible.

### BRIEF DESCRIPTION OF THE INVENTION

In one embodiment, a digital delay architecture is provided that includes at least one shifter, at least one adder connected to the at least one shifter and a plurality of registers storing at least an output of the at least one adder and an original sampled signal. The plurality of registers are selectable to define a fractional delay value.

In another embodiment, a digital delay architecture is provided that includes an integer delay line having a plurality of integer taps to define an integer delay and a fractional delay line configured to perform linear interpolation to define a fractional delay.

In yet another embodiment, a method for providing a digital delay includes generating an integer delay using a plurality of integer taps. The method further includes generating a fractional delay using at least one shifter.

### BRIEF DESCRIPTION OF THE DRAWINGS

FIG. 1 is a block diagram of a communication unit having a delay generator constructed in accordance with various embodiments of the invention.

FIG. 2 is a block diagram of a delay generator constructed in accordance with an embodiment of the invention.

FIG. 3 is a block diagram of a two tap fractional delay structure constructed in accordance with an embodiment of the invention.

FIG. 4 is a block diagram of a four tap fractional delay structure constructed in accordance with an embodiment of the invention.

FIG. 5 is a block diagram of an eight tap fractional delay structure constructed in accordance with an embodiment of the invention.

FIG. 6 is a block diagram of a fractional decimal delay structure constructed in accordance with an embodiment of the invention.

FIG. 7 is a block diagram of an integer delay line and a fractional delay line constructed in accordance with various embodiments of the invention.

### DETAILED DESCRIPTION OF THE INVENTION

For simplicity and ease of explanation, the invention will be described herein in connection with various embodiments thereof. Those skilled in the art will recognize, however, that the features and advantages of the various embodiments may be implemented in a variety of configurations. It is to be understood, therefore, that the embodiments described herein are presented by way of illustration, not of limitation.

Various embodiments of the present invention provide a delay for digital systems, especially digital systems with fractional structures. In general, the various embodiments provide fractional delays in incremental powers (e.g., powers of two) and/or fractional decimal delays. Although the various embodiments are described in connection with a particular application, for example, a wireless communication system for communicating audio, the various embodiments may be implemented in any system where digital delay lines are desired or needed and wherein different types of content are communicated.

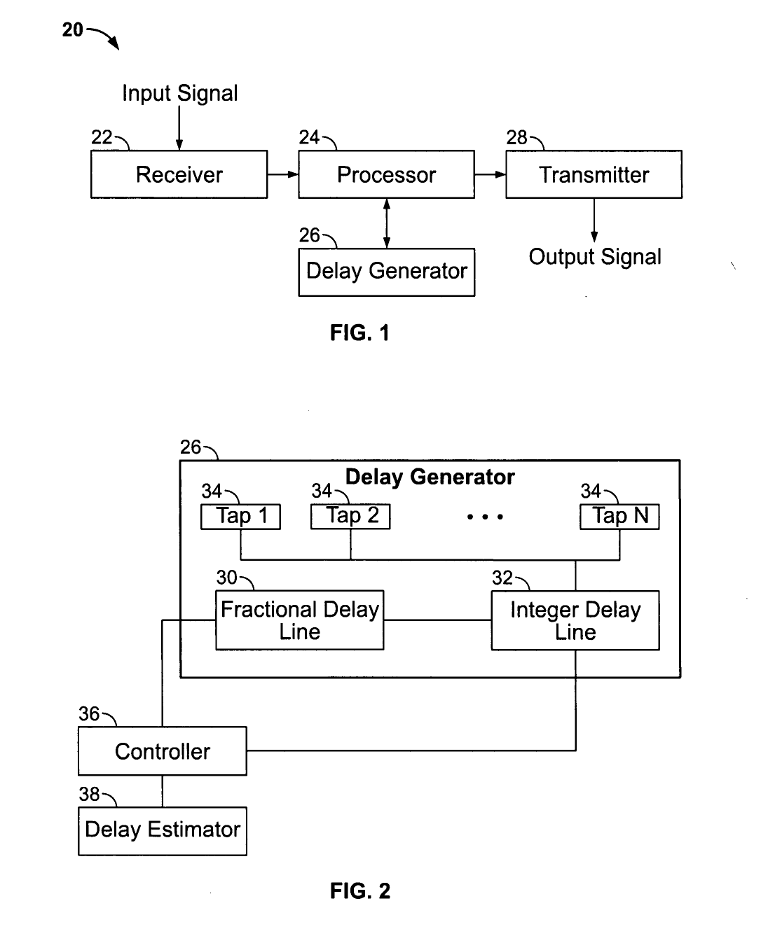

FIG. 1 shows a communication unit 20, for example, a cellular or radio unit for transmitting and receiving in a communication system, such as a cellular telephone system or land mobile radio system, respectively. The communication unit 20 includes a receiver 22 for receiving signals, for example, audio transmissions, such as analog audio transmissions. However, other signals carrying different content may be received, for example, signals carrying video content, voice content, data content, etc. The receiver 22 is connected to a processor 24 for processing the received signal. The processor 24 is connected to a delay generator 26 for generating a digital delay in accordance with various embodiments of the invention. The processor 24 is also connected to a transmitter 28 for transmitting the processed signal. The various components within the communication unit 20 may include digital and/or analog components.

In operation, the same received signal may be communicated through two paths in the communication unit 20 such that the two signals travel through different circuitry. After the signals pass through the two paths, for example, processed in different components, the processed signals may arrive at an output in the processor 24 shifted in time with respect to each other. This shift in time may be due to different factors, for example, signals require more time to travel through analog paths versus digital paths. These offset signals are aligned in time using the delay generator 26.

The delay generator 26 is shown in more detail in FIG. 2 and includes a fractional delay line component 30 (referred to herein as a fractional delay line 30) and an integer delay line component 32 (referred to herein as an integer delay line 32). The fractional delay line 30 is connected to the integer delay line 32, with the integer delay line 32 connected to one or more taps 34. The taps 34 are any storage or memory device or component capable of connecting to a line for sampling a signal on that line, for example, storage registers as described in more detail below. The taps 34 may be positioned at any point within a system to acquire the signal(s) to be time delayed and may sample the signals at certain clock rates (e.g., two clock delays, ten clock delays, fifteen clock delays, etc.).

The delay generator 26 is connected to a controller 36 that controls the operation of the delay generator 26. The controller 36 is connected to a delay estimator 38 that provides control signals to the controller that identifies the amount of delay needed. In operation, a path delay is estimated by the delay estimator 38 in any known manner, and as described in more detail below. The path delay may be estimated, for example, using a process such as synchronization that determines the path delay based on the alignment of amplitude and phase. Such a synchronization process useful for determining path delay is described in commonly assigned co-pending U.S. Patent Application entitled “Apparatus, System, and Method for Amplitude-Phase Synchronization in Polar Transmitter” having Ser. No. 11/396,122, filed Mar. 30, 2006, the entire disclosure of which is hereby incorporated by reference in its entirety. Other processes for estimating the path delay also may be provided, for example, by measurement.

For example, the amplitude and/or phase delay (or a correlation thereof) of a signal of interest, such as a received audio signal or an audio signal to be transmitted, is estimated. The determined estimated delay is then communicated to the controller 36 for use in controlling the delay generator 26 to generate the necessary delay. The amount of delay needed may be expressed, for example, as a time period, a number of clock cycles (and/or a fraction thereof), etc. The delay generator 26 then generates the delay that is introduced into the system or circuit where needed. For example, the estimated delay may be used in an amplitude or phase path to correctly align the two signals depending on which of the signals requires correction (e.g., correct the alignment of the signals). The delay may be provided in different portions of the system or circuit, for example, as digital audio delay lines, etc.

More particularly, for a continuous time system with an arbitrary delay, consider a delay element, which is a linear system with a purpose to delay an incoming continuous-time signal x_{c}(t) by τ (in seconds). The output signal y_{c}(t) of this system can be expressed as:

y_{c}(t)=x_{c}(t−τ) (1)

where the subscript ‘c’ refers to ‘continuous-time’. The Fourier transform X_{c}(Ω) of a continuous-time signal x_{c}(t) is then defined as:

$${X}_{c} ( Ω ) = {\int }_{- ∞}^{∞} {x}_{c} ( t ) {e}^{- j Ω t} d t \qquad ( 2 )$$

where Q=2πf is the angular frequency in radians. The Fourier transform Y_{c}(Ω) of the delayed signal y_{c}(t) can be expressed in terms of X_{c}(Ω) as:

$$\begin{matrix}{Y}_{c} ( Ω ) = {\int }_{- ∞}^{∞} {y}_{c} ( t ) {e}^{- j Ω t} d t \\ = {\int }_{- ∞}^{∞} {x}_{c} ( t - τ ) {e}^{- jΩ t} d t \\ = {e}^{- jΩτ} {X}_{c} ( Ω )\end{matrix} \qquad ( 3 )$$

The transfer function H_{d}(Ω) of the delay element then can be expressed by means of Fourier transforms X_{c}(Ω) and Y_{c}(Ω) as follows:

$${H}_{d} ( Ω ) = \frac{{Y}_{c} ( Ω )}{{X}_{c} ( Ω )} = \frac{{e}^{- jΩτ} {X}_{c} ( Ω )}{{X}_{c} ( Ω )} = {e}^{- jΩτ} \qquad ( 4 )$$

The term e^{-jΩτ} corresponds to the Fourier transform of the delay of τ.

For a discrete time delay system, the Fourier transform X_{c}(Ω) is non-zero only on a finite interval around ω=0, and the continuous-time signal x_{c}(t) is said to be band limited. The time signal may then be expressed by its samples x(nT), where nεZ is the sample index and T is the sample interval (i.e., the inverse of the sampling rate). In the discrete time version, the delay operation for a sampled band limited signal y(nT) can be expressed as:

y(nT)=x(nT−D) (5)

where D=τ/T is the desired delay as multiples of the unit delay. It should be noted that τ/T is generally irrational since T is usually not an integral multiple of sampling interval T. Equation 5 is meaningful only for integral values of D. The samples of the output sequence y(nT) are equal to the delayed samples of the input sequence x(nT) and the delay element may be called a digital delay line. If D were real, then the delay operation would not be this simple because the output value would be somewhere between the known samples of x(nT). The sample values of y(nT) would then have to be obtained by way of interpolation from the sequence x(nT). The spectrum of a discrete-time signal can be expressed by means of the discrete-time Fourier transform (DTFT). In this integral transform, the time variable is discretized, but the frequency variable is continuous. The DTFT of signal x(nT) is defined as:

$$X ( ω ) = {\sum }_{n = - ∞}^{∞} x ( nT ) {e}^{- jω n} , \vert ω \vert \leq π \qquad ( 6 )$$

where ω=2πfT is the normalized angular frequency. The DTFT of the output signal y(nT) can be expressed as:

$$\begin{matrix}Y ( ω ) = {\sum }_{n = - ∞}^{∞} y ( nT ) {e}^{- jω n} \\ = {\sum }_{n = - ∞}^{∞} x ( nT - D ) {e}^{- jω n} \\ = {e}^{- j ω D} X ( ω )\end{matrix} \qquad ( 7 )$$

The transfer function of an ideal discrete-time delay element can be expressed as:

$${H}_{d} ( ω ) = \frac{Y ( ω )}{X ( ω )} = \frac{{e}^{- j ω D} X ( ω )}{X ( ω )} = {e}^{- jω D} , \vert ω \vert \leq π \qquad ( 8 )$$

Replacing the continuous Fourier transform operator, which is representative of the angular frequency, with the discrete time z-transform operator representative of the circular frequency due to discretization, Equation 8 now becomes:

$${H}_{d} ( ω ) = \frac{Y ( z )}{X ( z )} = \frac{{z}^{- D} X ( z )}{X ( z )} = {z}^{- D} \qquad ( 9 )$$

where D□R₊ is the length of the delay in samples. The delay D can be expressed as:

D=Dᵢₙₜ+D_{frac} (10)

where Dᵢₙₜ is the integer delay and D_{frac} is the fraction whose range is between

0≦D_{frac}<1.

In order to produce a fractional delay in the discrete time system the signal is interpolated. Interpolation of a discrete time signal is possible because the amplitude of the corresponding continuous time band limited signal changes smoothly between the sampling instants. The value of the fractional delay can in principle be any value between 0 and 1. In order to produce any arbitrary fractional delay for a discrete time signal x(nT), it must be known how to compute the amplitude of the underlying continuous time signal x(t) for all t.

Shannon's sampling theorem states that in order to reconstruct any signal within intervals (−f_{c}, f_{c}) in the Fourier domain the signal needs to be sampled at twice the rate of f_{c}. Using cardinal series, the reconstruction formula for a sampled signal is:

$$\begin{matrix}{x}_{c} ( t ) = {\sum }_{n = - ∞}^{∞} x ( nT ) \frac{sin ( \frac{{ω}_{s}}{2} ( t - nT ) )}{\frac{{ω}_{s}}{2} ( t - nT )} \\ = {\sum }_{n = - ∞}^{∞} x ( nT ) sin c ( \frac{{ω}_{s}}{2 π} ( t - nT ) )\end{matrix} \qquad ( 11 )$$

where ωₛ=2πfₛ is the sampling angular frequency in radians per second and T=1/fₛ is the corresponding sampling interval. The sinc function is defined as:

$$sin c ( t ) = \frac{sin ( π t )}{π t} \\ The {lim}_{t -> 0} \{ \frac{sin ( π t )}{π t} \} = 1 , \\ and thereby sin c ( 0 ) = 1. \qquad ( 12 )$$

From Equation 11, the ideal band limited interpolator has a continuous time impulse response as follows:

$${h}_{c} ( t ) = \frac{sin ( \frac{{ω}_{s} t}{2} )}{\frac{{ω}_{s} t}{2}} = sin c ( \frac{{ω}_{s} t}{2 π} ) \\ for \\ t ∈ R . \qquad ( 13 )$$

The desired delay D may be obtained by shifting Equation 13 by D and then sampling D at equidistant points. Hence the output y(n) of the ideal discrete time fractional delay element is computed as:

$$y ( n ) = x ( n - D ) = {\sum }_{k = - ∞}^{∞} x ( k ) sin c ( n - D - k ) \qquad ( 14 )$$

for nεZ and DεR. Thus, in order to produce a fractional delay reconstruction of the discrete time signal and shifted re-sampling of the resulting continuous time signal as represented in Equation 14 is performed.

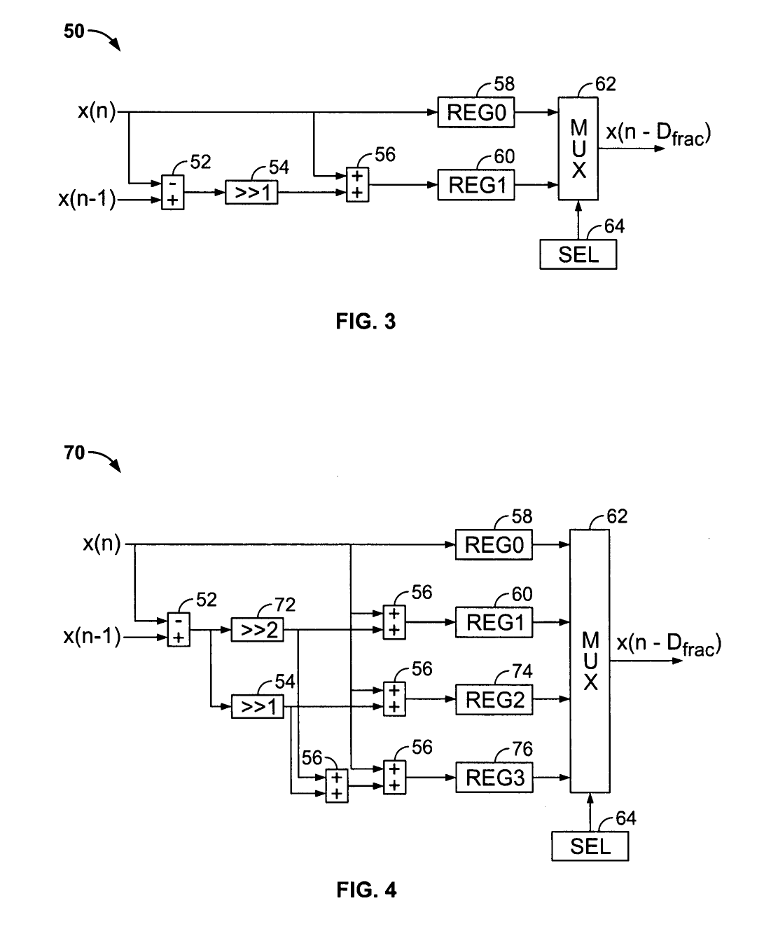

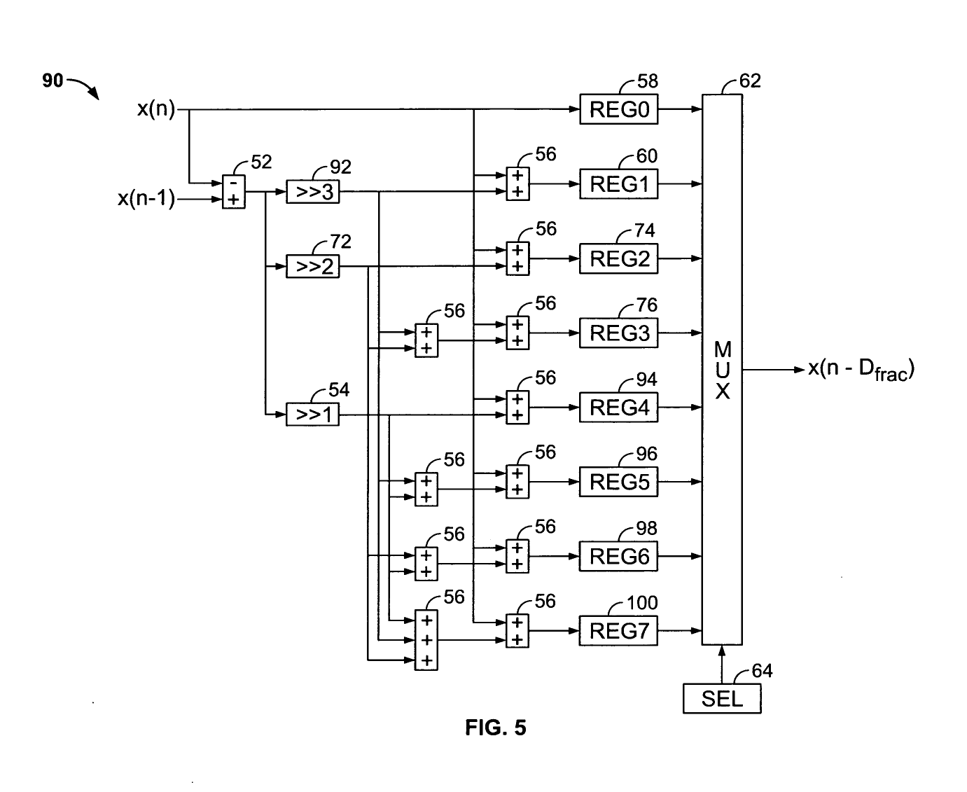

The desired delay D may be generated using the delay generator 26 by generating a fractional digital delay and an integer digital delay (also referred to as a real digital delay). The fractional delay line 30 may be implemented to generate different incremental fractional delays, the resolution of which is based on the number of taps 34 provided. The fractional delay is generated without the use of digital multipliers. In general, the fractional delay line 30 is formed from a digital architecture, for example in an ASIC, wherein different resolutions may be provided as defined by ½^{N}, where N is the number of taps of the fractional delay structure. In particular, the fractional delay line 30 may be implemented using a two tap structure 50 as shown in FIG. 3 that defines a two tap fractional digital delay line, a four tap structure 70 as shown in FIG. 4 that defines a four tap fractional digital delay line, and an eight tap structure 90 as shown in FIG. 5 that defines an eight tap fractional delay line. The taps 34 (shown in FIG. 2), are generally represented by registers in the various embodiments illustrated in FIGS. 3 through 5 below. Essentially, each tap 34 represents or corresponds to a single clock cycle delay. For example, if the signal is sampled from a second tap, then the signal is delayed by two clock cycles.

Referring to FIG. 3, the two tap structure 50 includes a subtractor 52 that receives signal samples at inputs of the subtractor 52, namely x(n) and x(n−1), with x(n) being the current integer sample signal value and x(n−1) being the previous integer sample value (using the sampling clock at which these signals are sampled). The output of the subtractor 52 is connected to a shifter 54, which in this embodiment is a shift by one shifter. The output of the shifter 54 is connected to one input of an adder 56 with the x(n) signal provided to the other input of the adder 56. A first register 58 (REG 0), for example, a memory location, receives the x(n) signal, namely the original received signal (e.g., an analog signal to be delayed) and a second register 60 (REG 1) is connected to and receives the output of the adder 60. The output of the first and second registers 58 and 60 are connected to the inputs of a multiplexer 62. A selector 64 is connected to the multiplexer 62 to select inputs to provide as an output x(n-D_{frac}).

In operation, the input signals are subtracted by the subtractor and then shifted by one by the shifter 54 (e.g., a one binary bit shift). Thereafter the output of the shifter 54 is added to the signal to be delayed and stored in the second register 60 with the original signal stored in the first register 58. The registers 58 and 60, and generally as described herein, are storage elements configured to hold or store signal value or data, which in this embodiment, operate as delay elements. Thereafter, different combinations of the register outputs may be selected such that D_{frac} can be two different values, namely 0 and 0.5.

Referring to FIG. 4, the four tap structure 70 is similar to the two tap structure 50 with the addition of a second shifter 72, which in this embodiment is a shift by two shifter. The outputs of the first shifter 54 and the second shifter 72 are added individually to the original signal x(n) and also added together and then the results added to the original signal x(n) by the adders 56 (four adders 56 are provided in this embodiment). The outputs of the adders 56 are then stored in the first and second registers 58 and 60 as well as additional registers, namely a third register 74 (REG 2) and a fourth register 76 (REG 3). Using this four tap structure 70, the selector 64 may be used to select between four different inputs to the multiplexer 62 from the register outputs such that D_{frac} can be four different values, namely 0, 0.25, 0.5 and 0.75.

Referring to FIG. 5, the eight tap structure 90 is similar to the four tap structure 70 with the addition of a third shifter 92, which in this embodiment is a shift by three shifter. The outputs of the first shifter 54, the second shifter 72 and the third shifter 92 are added individually to the original signal x(n), added together in pairs of two and also added all three together and then the results each added to the original signal x(n) by the adders 56 (eleven adders 56 are provided in this embodiment). The outputs of the adders 56 are then stored in the first, second, third and fourth registers 58, 60, 74 and 76 as well as additional registers, namely a fifth register 94 (REG 4), a sixth register 96 (REG 5), a seventh register 98 (REG 6) and an eight register 100 (REG 7). Using this eight tap structure 90, the selector 64 may be used to select between eight different inputs to the multiplexer 62 from the register outputs such that D_{frac} can be eight different values, namely 0, 0.125, 0.25, 0.375, 0.5, 0.625, 0.75 and 0.875.

Thus, for the two tap structure 50, a fractional resolution of 1/2 is provided. For the four tap structure 70, a fractional resolution of ¼ is provided. For the eight tap structure 90, a fractional resolution of ⅛ is provided. Additional embodiments are contemplated with different numbers of taps to provide different levels of resolution such that for an N tap structure the fractional resolution is 1/N where N is a power of two.

Further, the fractional delay line 30 may be provided with higher order taps with the order for this fractional delay line being a power of 2. Accordingly, for an N=2^{p} tap structure with N registers, p shifters would be required and p*2^{p-1} adders would be required, with p being a positive integer value.

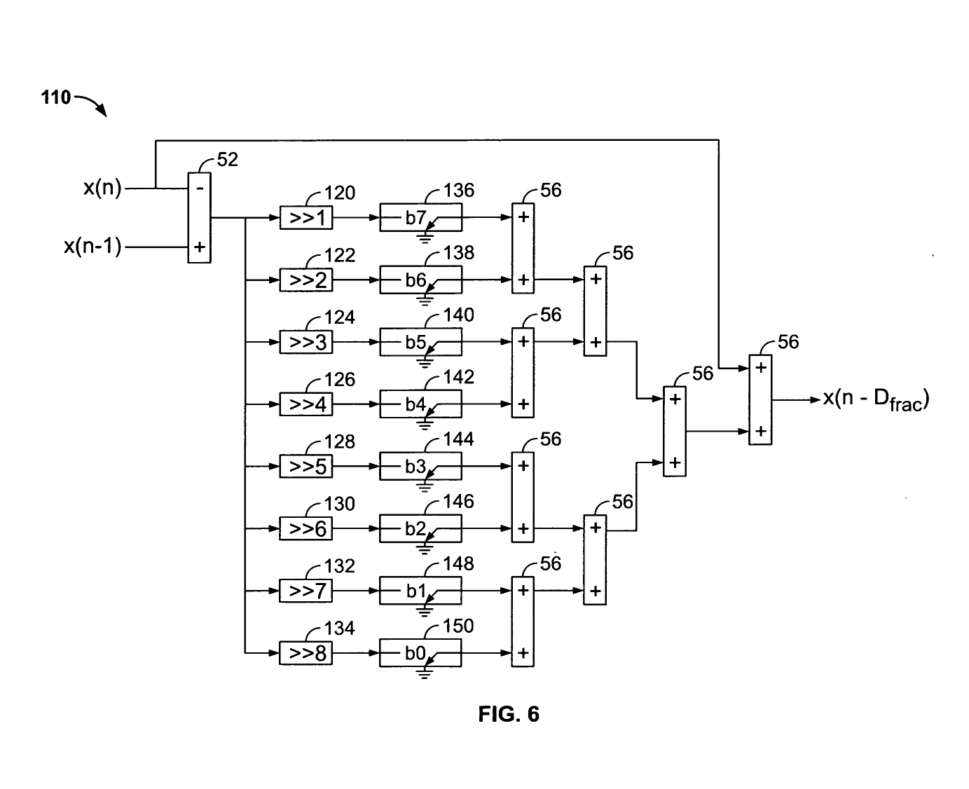

In another embodiment as shown in FIG. 6, the fractional delay line 30 may be implemented using a fractional decimal delay structure 110. In this embodiment, the fractional part is represented by eight bits that would be able to provide a delay up to two decimal places. It should be noted that the fractional decimal delay structure 110 may be modified to a higher number of bits (N bits) if more precision is needed or desired. In this embodiment, eight shifters 120-134 are provided and connected to the output of the subtractor 52. The shifters 120-134 are configured as shift by one through shift by eight registers, respectively, each incremented by one. The output of each of the shifters 120-134 are connected to respective registers 136-150. The outputs of each pair of registers, for example, registers 136 and 138 are connected to an adder 56, with the outputs of pairs of adders 56 connected to another adder 56, with a final adder 56 receiving the output from the previous adders 56 and the original signal x(n).

In operation, the signals x(n) and x(n−1) are received at the input of the subtractor 52, the output of which is shifted by the all the shifters 120-134 (such that a fractional precision of eight bits is provided) that are then switched depending on the bits in the registers 136-150, namely D_{frac} registers [b₇b₆b₅b₄b₃b₂b₁b₀]. If the corresponding bit is a ‘1’ then the output of the shifter is selected and if the output is a ‘0’ then the value=0 (GND) is selected and fed to the adders 56. This operation is performed by all the switches and after traversing through the different adders in the path the final output is a fractional delayed by D_{frac}, namely x(n−D_{frac}).

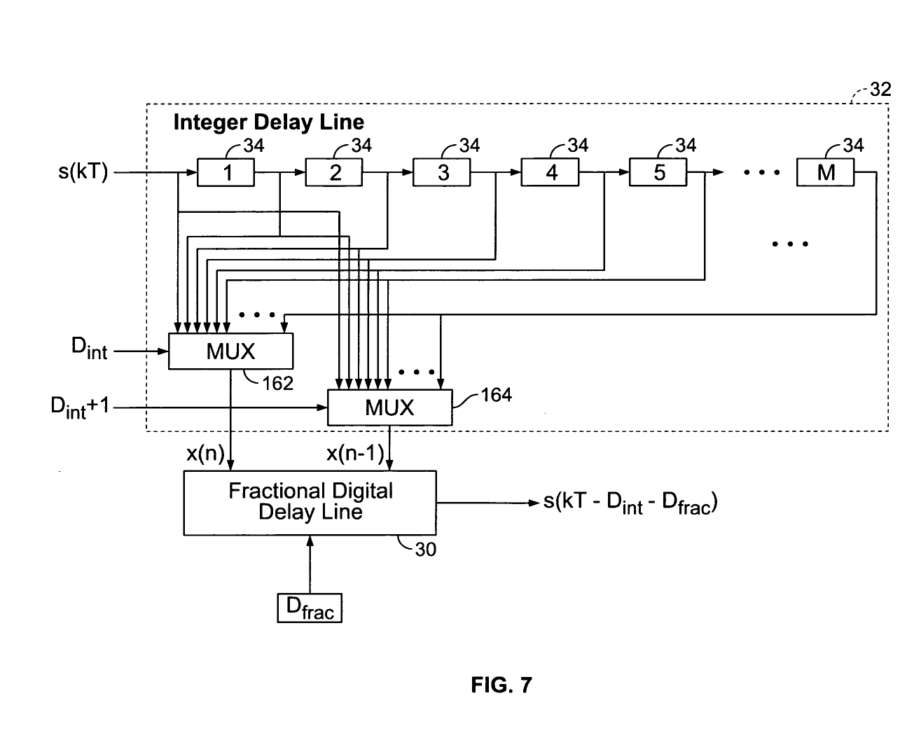

Various embodiments provide a delay that is defined by a fractional component generated by the fractional delay line 30 as described above and an integer delay component generated by an integer delay line 32 as described in more detail below. Thus, a combination of integer delays plus fractional delays is provided. As shown in FIG. 7 (which may be referred to as a real digital delay line structure), the integer delay line 32 includes a plurality of integer taps, for example the taps 34, each connected to a first multiplexer 162 and a second multiplexer 164, the outputs of which are connected to the fractional delay line 30. It should be noted that the taps 34 may be provided as part of the integer delay line 32 as shown in FIG. 7 or may be provided separately as shown in FIG. 2.

In operation, the value of the taps 34 is determined by the duration of the delay required and the clock rate at which the delay line operates. The Dᵢₙₜ signal input to the first multiplexer 162 selects the integer delay tap (e.g., tap value) through the first multiplexer 162 with the first multiplexer 162 connected to the x(n) input of the fractional delay line 30 providing that tap value to the x(n) input. The Dᵢₙₜ+1 signal is input to the second multiplexer 164 to select the integer delay tap through the second multiplexer 164 with the second multiplexer 162 connected to the x(n−1) input of the fractional delay line 30 providing the tap value to the x(n−1) input. The fractional part of the value (e.g., a fractional value for which the delay needs to be provided) is registered as D_{frac} that takes only fractional values that are a power of two as described above. The D_{frac} value is used by the selector 64 (shown in FIGS. 3 through 5) to select the corresponding output via the multiplexer 62 (shown in FIGS. 3 through 5) and in the decimal digital delay line 110 (shown in FIG. 6) the D_{frac} value is used by the registers 136-150 to determine the fractional delay as described in more detail above.

Thus, the signal s(kT) to be delayed by an amount Dᵢₙₜ+D_{frac} is fed to the integer delay line 32 shown in FIGS. 2 and 7. The Dᵢₙₜ value extracts the signal sample from the corresponding integer tap delay line via the first multiplexer 162 and provides the value to the x(n) input of the fractional delay line 30 and similarly the Dᵢₙₜ+1 value extracts the signal sample from the corresponding integer tap delay line via the second multiplexer 164 and provides the value to the x(n−1) input of the fractional delay line 30. The D_{frac} value is then used by the selector 64 of the fractional delay line 30 to extract the delayed output.

The integer delay line 32 delays the input s(kT) by an amount Dᵢₙₜ and, thus, the input x(n) and x(n−1) are defined as follows:

x(n)=s(kT−Dᵢₙₜ (15)

x(n−1)=s(kT−Dᵢₙₜ−1) (16)

The output of the fractional delay line 30, which is also the final output of the real digital delay structure, is the signal s(kT) is delayed by a real value amount Dᵢₙₜ+D_{frac}, thus generating a signal equal to s(kT−Dᵢₙₜ−D_{frac}).

In the various embodiments, and referring, for example, to FIGS. 4 and 7, assume that the sampling rate is Fs with the required real valued delay Dtot=2.25. At the sampling rate Fs the integer delay line, for example, the integer delay line component 32 (shown in FIG. 7) first introduces the integer delay Dint=2 by selecting the value output from the taps 34 labeled “2” and “3”. These values are provided to the fractional digital delay line, for example, the fractional delay line component 30, with the select value Dfrac (shown in FIG. 7) equal to SEL (shown in FIG. 4) of the four tap fractional digital delay line, for example, the four tap structure 70, set to ‘01’ to represent the fractional value of 0.25. Accordingly, consider the sequence “4, 8, 12, 16, 20, . . . ” coming into the real digital delay line structure shown in FIG. 7. This would produce a corresponding output of “0, 0, 3, 7, 11, 15, 19, . . . ”

It should be noted that for a delay, for example, the delay of 2.25, the sequence for the delay may vary from time to time. For example, and using the delay of 2.25, if the sampling rate is 52 MHz (about 19.23 nanoseconds (ns)), then a delay of 2.25 translates to a 43.26 ns delay. In this delay of 43.26 ns, 38.46 ns is translated (and corresponds) to two integer delays and the remaining 4.80 ns is translated (and corresponds) to a 0.25 fractional delay (which is the fractional delay portion).

Thus, the various embodiments provide a digital delay structure that implements fractional delays without the use of multipliers. This implementation results in reduced power consumption and less space needed to accommodate the structure.

While the invention has been described in terms of various specific embodiments, those skilled in the art will recognize that the various embodiments of the invention can be practiced with modification within the spirit and scope of the claims.

What is claimed is:

1. A digital delay architecture comprising:
at least one shifter;
at least one adder connected to the at least one shifter; and
a plurality of registers storing at least an output of the at least one adder and an original sampled signal, the plurality of registers selectable to define a fractional delay value.

2. A digital delay architecture in accordance with claim 1 wherein the at least one shifter comprises a shift by one register.

3. A digital delay architecture in accordance with claim 1 further comprising a plurality of shifters providing incremental shifting by a value of N, where N is an integer value.

4. A digital delay architecture in accordance with claim 1 further comprising a subtractor connected to the at least one shifter.

5. A digital delay architecture in accordance with claim 4 wherein the subtractor is configured to receive two sampled signals.

6. A digital delay architecture in accordance with claim 1 further comprising a multiplexer configured to select at least one output from the plurality of registers to define the fractional delay.

7. A digital delay architecture in accordance with claim 1 further comprising a plurality of shifters and a plurality of adders connected to each of the plurality of shifters and to pairs of the plurality of shifters.

8. A digital delay architecture in accordance with claim 1 further comprising a plurality of integer taps configured to define an integer delay value and to select the plurality of registers to define the fractional delay.

9. A digital delay architecture comprising:
an integer delay line having a plurality of integer taps to define an integer delay; and
a fractional delay line configured to perform linear interpolation to define a fractional delay.

10. A digital delay architecture in accordance with claim 9 wherein the fractional delay line does not comprise any multipliers.

11. A digital delay architecture in accordance with claim 9 wherein the fractional delay line comprises a plurality of shift by N shifters, where N is an incremental integer value.

12. A digital delay architecture in accordance with claim 9 further comprising a number of taps defining a fractional delay resolution.

13. A digital delay architecture in accordance with claim 9 wherein the fractional delay line is configured to perform a decimal digital delay using a plurality of shift registers and a plurality of adders.

14. A digital delay architecture in accordance with claim 9 wherein a number of the plurality of integer taps is determined based on a delay duration and a clock rate.

15. A digital delay architecture in accordance with claim 9 wherein a total delay is defined by a real value amount determined by the integer delay and the fractional delay.

16. A method for providing a digital delay, said method comprising:
generating an integer delay using a plurality of integer taps; and
generating a fractional delay using at least one shifter.

17. A method in accordance with claim 16 wherein the at least one shifter comprises a shift by N register, where N is an integer value.

18. A method in accordance with claim 16 wherein the fractional delay is generated without using any multipliers.

19. A method in accordance with claim 16 further comprising adding the output of the at least one shifter with a sampled signal.

20. A method in accordance with claim 16 further comprising selecting a fractional delay based on a value of one of the plurality of integer taps.
